(19) United States
(12) Patent Application Publication
(10) Pub. No.: US 2026/0056244 A1
(43) Pub. Date: Feb. 26, 2026

(54) DETERMINING AN OPERATIONAL LIMIT FOR A TRANSISTOR DEVICE WITH AGING RECOVERY

(71) Applicant: Microchip Technology Inc., Chandler, AZ (US)

(72) Inventors: Mazhar Hoque, Gilbert, AZ (US); Samir Fuke, Tempe, AZ (US); Amit Rai, Chandler, AZ (US); Joseph Rascon, Chandler, AZ (US); Hoi Yun Henry Chan, Lachine (CA)

(73) Assignee: Microchip Technology Inc., Chandler, AZ (US)

(21) Appl. No.: 19/295,137

(22) Filed: Aug. 8, 2025

Related U.S. Application Data
(63) Continuation-in-part of application No. 18/810,767, filed on Aug. 21, 2024.
(63) Continuation-in-part of application No. 19/036,836, filed on Jan. 24, 2025.
(60) Provisional application No. 63/727,456, filed on Dec. 3, 2024.
(60) Provisional application No. 63/811,641, filed on May 24, 2025.

(30) Foreign Application Priority Data
Apr. 30, 2024 (IN) 202411034408

(51) Int. Cl. G01R 31/26

(52) U.S. Cl. CPC G01R 31/2642

(57) ABSTRACT

Systems and methods for determining an operational limit for a transistor are disclosed. The method may include receiving a set of input parameters related to a transistor and performing an age-dependent analysis based on the input parameters. The age-dependent analysis may include performing a non-aging simulation of the transistor by simulating a non-aging operation of the transistor and performing a plurality of aging simulations of the transistor based on aging conditions specified by the input parameters, a different value of at least one operational parameter of the transistor, and an aging recovery effect of the transistor as a function of a usage parameter of the transistor. The analysis may further include comparing respective results of the aging simulations with a result of the non-aging simulation. The method may include determining an operational limit for the transistor based at least on a result of the age-dependent analysis of the transistor.

### PRIORITY

This application is a continuation-in-part of U.S. patent application Ser. No. 18/810,767 filed Aug. 21, 2024 and Ser. No. 19/036,836 filed Jan. 24, 2025, and claims priority to U.S. Provisional Patent Application Nos. 63/811,641 filed May 24, 2025, and 63/727,456 dated Dec. 3, 2024, the contents of which are hereby incorporated in their entirety.

### TECHNICAL FIELD

The present disclosure relates to determining an operational limit for a transistor device

### BACKGROUND

The performance of electronic circuit components, for example transistors and other semiconductor devices, typically degrades over time due to one or more factors, for example hot carrier injection (HCI), bias temperature instability (BTI), or any combination thereof, without limitation. This age-dependent degradation is particularly significant in certain advanced semiconductor process technology nodes, for example technologies of 55 nm and below.

A circuit designer or manufacturer using an Electronic Design Automation (EDA) tool (for example a Cadence, Synopsys, or Ansys EDA platform) to design a circuit, may attempt to determine operational ranges for respective circuit components (e.g., transistors) that allow for long-term operation with acceptable age-related degradation. Such operational range is often referred to as a safe operating area (SOA), the extents of which are referred to as SOA limits. Conventional techniques for determining SOA limits include using a spreadsheet (e.g., Excel) or other online calculator. Such techniques are generally primitive, providing a rough estimate of SOA limits, and often inaccurate. Conventional techniques typically involve checking the performance of each circuit components by a largely manual process, performed outside the relevant design environment, e.g., outside the EDA tool used for the relevant circuit design. This largely manual checking of circuit components may be slow and time consuming.

Conventional tools often require a separate calculation process for each mode of degradation, e.g., BTI and HCI, and cannot analyze BTI and HCI collectively. In addition, conventional tools typically cannot check a recovery factor for BTI, HCI, or both. In addition, for transistor design, conventional tools typically provide a generic maximum operational voltage, without differentiating between drain-source voltage (Vds) and gate-source voltage (Vgs), and typically cannot provide a maximum body-source voltage (Vbs).

Conventional EDA tools typically have some capability to run aging simulations, but such simulations can be time-consuming. In addition, such aging simulations are typically performed at the end of the circuit design cycle, thus often require an extensive redesign of the circuit in response to the aging simulation results. Still further, EDA tools typically do not have the capability to generate maximum allowable voltage limits for a specific application.

### SUMMARY OF THE INVENTION

Aspects provide systems and methods for determining an operational limit for a transistor device. Examples of the present disclosure may include a non-transitory computer-readable medium. The non-transitory computer-readable medium may include instructions executable by a processor. The instructions may cause the processor to receive a set of input parameters related to a transistor device. The instructions may cause the processor to perform an age-dependent analysis of the transistor device based on the set of input parameters. The age-dependent analysis may include performing a non-aging simulation of the transistor device by simulating a non-aging operation of the transistor device. The age-dependent analysis may also include performing a series of aging simulations of the transistor device. Each aging simulation may include a simulation of an aging operation of the transistor device based on (a) aging conditions specified by the input parameters, (b) a different value of at least one operational parameter of the transistor device, wherein at least one operational parameter of the transistor device comprises at least one of a gate-source voltage (Vgs), a drain-source voltage (Vds), or a body-source voltage (Vbs), and (c) an aging recovery effect of the transistor device as a function of a usage parameter of the transistor device. The age-dependent analysis may further include comparing respective results of the series of aging simulations with a result of the non-aging simulation. The instructions may cause the processor to determine an operational limit for the transistor device based at least on a result of the age-dependent analysis of the transistor device. The operational limit may include a maximum operating value of the gate-source voltage (Vgs), the drain-source voltage (Vds), or the body-source voltage (Vbs).

In combination with any of the above examples, the instructions may be further executable by the processor to apply the operational limit to a circuit design to detect design violations.

In combination with any of the above examples, the operational limit may be a safe operating area (SOA) limit for the transistor device.

In combination with any of the above examples, the non-aging simulation and the plurality of aging simulations of the transistor device may be performed by a SPICE simulator.

In combination with any of the above examples, the aging simulation in the plurality of aging simulations of the transistor device may include a simulation of the aging operation of the transistor device based on (a) the aging condition specified by the input parameters, (b) a different parameter value combination for at least two operational parameters of the transistor device, and (c) the aging recovery effect of the transistor device as a function of a usage parameter of the transistor device.

In combination with any of the above examples, performing the plurality of aging simulations of the transistor device may include performing multiple aging simulations of the transistor device for each of multiple different values of a first operational parameter of the transistor device. The multiple aging simulations for a respective value of the first operational parameter may include respective aging simulations based on (a) the aging condition specified by the input parameters, (b) the respective value of the first operational parameter, (c) multiple different values of a second operational parameter of the transistor device, and (d) the aging recovery effect of the transistor device as a function of a usage parameter of the transistor device. The age-dependent analysis may include determining, for each of at least two of the multiple different values of the first operational parameter, a respective limit value derived from results of the multiple aging simulations performed for the respective value of the first operational parameter. The age-dependent analysis may also include determining the operational limit for the transistor device based at least on a result of the age-dependent analysis of the transistor device includes selecting a highest or lowest value of the at least two limit values as the operational limit for the transistor device.

In combination with any of the above examples, the instructions may be further executable by the processor to determine the operational limit for the transistor device based on a duration of an overvoltage stress applied to the transistor device.

In combination with any of the above examples, the non-aging simulation of the transistor device may include simulating an effect of the non-aging operation of the transistor device on a performance metric specified in the set of input parameters. The aging simulation of the transistor device may include simulating an effect of the aging operation of the transistor device on the performance metric.

In combination with any of the above examples, the performance metric may be a saturation drain current (Idsat), a linear drain current (Idlin), or a linear threshold voltage (Vtlin).

In combination with any of the above examples, performing the non-aging simulation of the transistor device may include simulating a non-aging operation of a non-aged model of the transistor device derived from the set of input parameters. Performing a respective aging simulation of the transistor device in the plurality of aging simulations may include simulating an aging operation of the non-aged model of the transistor device, generating an aged model of the transistor device based on results of the aging operation of the non-aged model of the transistor device, and simulating an operation of the aged model of the transistor device.

Alone or in combination with any of the above examples, examples of the present disclosure may include a non-transitory computer-readable medium. The non-transitory computer-readable medium may include instructions executable by a processor. The instructions may cause the processor to receive a set of input parameters related to a transistor. The instructions may cause the processor to perform an age-dependent analysis of the transistor. The age-dependent analysis may include performing a non-aging simulation of the transistor by simulating a non-aging operation of the transistor to determine a non-aged value of a performance metric. The age-dependent analysis may also include performing a plurality of aging simulations of the transistor. Performing an aging simulation in the plurality of aging simulations may include simulating an aging operation of the transistor, using (a) aging conditions specified by the input parameters, (b) a different value of at least one operational parameter of the transistor, wherein at least one operational parameter of the transistor device comprises at least one of a gate-source voltage (Vgs), a drain-source voltage (Vds), or a body-source voltage (Vbs), and (c) an aging recovery effect of the transistor as a function of a usage parameter of the transistor, to determine a respective aged value of the performance metric corresponding with the respective value of a first operational parameter. The age-dependent analysis may include, for each respective aging simulation, comparing (a) the respective aged value of the performance metric corresponding with the respective value of the first operational parameter with (b) the non-aged value of the performance metric to determine a respective aging-based change in the performance metric corresponding with the respective value of the first operational parameter. The age-dependent analysis may further include determining, based on the respective aging-based changes in the performance metric corresponding with the respective values of the first operational parameter, a limit value of the first operational parameter corresponding with a threshold value of the performance metric. The instructions may further cause the processor to determine an operational limit for the transistor based at least on the determined limit value of the first operational parameter, wherein the operational limit comprises a maximum operating value of the gate-source voltage (Vgs), the drain-source voltage (Vds), or the body-source voltage (Vbs).

In combination with any of the above examples, the instructions may be further executable by the processor to apply the operational limit to a circuit design to detect design violations.

In combination with any of the above examples, the operational limit may be a safe operating area (SOA) limit for the transistor.

In combination with any of the above examples, performing the plurality of aging simulations of the transistor may include performing multiple aging simulations of the transistor for each of the multiple different values of the first operational parameter of the transistor. The multiple aging simulations for the respective value of the first operational parameter may include respective aging simulations based on (a) an aging condition specified by the input parameters, (b) the respective value of the first operational parameter, (c) multiple different values of a second operational parameter of the transistor, and (d) the aging recovery effect of the transistor as a function of a usage parameter of the transistor. The age-dependent analysis may include determining, for each of at least two of the multiple different values of the first operational parameter, a respective limit value derived from results of the multiple aging simulations performed for the respective value of the first operational parameter. The age-dependent analysis may also include determining the operational limit for the transistor based at least on a result of the age-dependent analysis of the transistor includes selecting a highest or lowest value of the at least two limit values as the operational limit for the transistor.

In combination with any of the above examples, the instructions may be further executable by the processor to determine the operational limit for the transistor device based on a duration of an overvoltage stress applied to the transistor device.

In combination with any of the above examples, the non-aging simulation of the transistor may include simulating an effect of the non-aging operation of the transistor on the performance metric specified in the set of input parameters. The aging simulation of the transistor may include simulating an effect of the aging operation of the transistor on the performance metric.

In combination with any of the above examples, the performance metric may be a saturation drain current (Idsat), a linear drain current (Idlin), or a linear threshold voltage (Vtlin).

Alone or in combination with any of the above examples, examples of the present disclosure may include a method. The method may include receiving a set of input parameters related to a transistor device. The method may also include performing an age-dependent analysis of the transistor device based on the set of input parameters. The age-dependent analysis may include performing a non-aging simulation of the transistor device by simulating a non-aging operation of the transistor device. The age-dependent analysis may also include performing a plurality of aging simulations of the transistor device, an aging simulation of the plurality of aging simulations including a simulation of an aging operation of the transistor device based on (a) aging conditions specified by the input parameters, (b) a different value of at least one operational parameter of the transistor device, wherein at least one operational parameter of the transistor device comprises at least one of a gate-source voltage (Vgs), a drain-source voltage (Vds), or a body-source voltage (Vbs), and (c) an aging recovery effect of the transistor as a function of a usage parameter of the transistor device. The age-dependent analysis may further include comparing respective results of the plurality of aging simulations with a result of the non-aging simulation. The method may include determining an operational limit for the transistor device based at least on a result of the age-dependent analysis of the transistor device. The operational limit may be a maximum operating value of the gate-source voltage (Vgs), the drain-source voltage (Vds), or the body-source voltage (Vbs).

In combination with any of the above examples, the aging simulation in the plurality of aging simulations of the transistor device may include a simulation of the aging operation of the transistor device based on (a) the aging condition specified by the input parameters, (b) a different parameter value combination for at least two operational parameters of the transistor device, and (c) the aging recovery effect of the transistor device as a function of a usage parameter of the transistor device.

In combination with any of the above examples, performing the plurality of aging simulations of the transistor device may include performing multiple aging simulations of the transistor device for each of multiple different values of a first operational parameter of the transistor device. The multiple aging simulations for a respective value of the first operational parameter may include respective aging simulations based on (a) the aging conditions specified by the input parameters, (b) the respective value of the first operational parameter, (c) multiple different values of a second operational parameter of the transistor device, and (d) the aging recovery effect of the transistor as a function of a usage parameter of the transistor device. The age-dependent analysis may include determining, for each of at least two of the multiple different values of the first operational parameter, a respective limit value derived from results of the multiple aging simulations performed for the respective value of the first operational parameter. The age-dependent analysis may also include determining the operational limit for the transistor device based at least on a result of the age-dependent analysis of the transistor device includes selecting a highest or lowest value of the at least two limit values as the operational limit for the transistor device.

In combination with any of the above examples, the method may include determining the operational limit for the transistor device based on a duration of an overvoltage stress applied to the transistor device.

In combination with any of the above examples, the non-aging simulation of the transistor device may include simulating an effect of the non-aging operation of the transistor device on a performance metric specified in the set of input parameters. The aging simulation of the transistor device may include simulating an effect of the aging operation of the transistor device on the performance metric.

Alone or in combination with any of the above examples, examples of the present disclosure may include a system. The system may include an electronic design automation (EDA) tool for development of circuit design including a transistor device. The system may also include an operational limit generation system integrated in the EDA tool. The operational limit generation system may include instructions stored in non-transitory computer-readable medium and executable by a processor. The instructions may cause the processor to receive a set of input parameters related to a transistor device. The instructions may also cause the processor to perform an age-dependent analysis of the transistor device based on the set of input parameters. The age-dependent analysis may include performing a non-aging simulation of the transistor device by simulating a non-aging operation of the transistor device. The age-dependent analysis may also include performing a plurality of aging simulations of the transistor device. The aging simulation of the plurality of aging simulations may include a simulation of an aging operation of the transistor device based on (a) aging conditions specified by the input parameters, (b) a different value of at least one operational parameter of the transistor device, wherein at least one operational parameter of the transistor device comprises at least one of a gate-source voltage (Vgs), a drain-source voltage (Vds), or a body-source voltage (Vbs), and (c) an aging recovery effect of the transistor as a function of a usage parameter of the transistor device. The age-dependent analysis may further include comparing respective results of the plurality of aging simulations with a result of the non-aging simulation. The instructions may further cause the processor to determine an operational limit for the transistor device based at least on a result of the age-dependent analysis of the transistor device. The operational limit may be a maximum operating value of the gate-source voltage (Vgs), the drain-source voltage (Vds), or the body-source voltage (Vbs).

In combination with any of the above examples, the aging simulation in the plurality of aging simulations of the transistor device may include a simulation of the aging operation of the transistor device based on (a) the aging condition specified by the input parameters, (b) a different parameter value combination for at least two operational parameters of the transistor device, and (c) the aging recovery effect of the transistor device as a function of a usage parameter of the transistor device.

In combination with any of the above examples, performing the plurality of aging simulations of the transistor device may include performing multiple aging simulations of the transistor device for each of multiple different values of a first operational parameter of the transistor device. The multiple aging simulations for a respective value of the first operational parameter may include respective aging simulations based on (a) the aging conditions specified by the input parameters, (b) the respective value of the first operational parameter, (c) multiple different values of a second operational parameter of the transistor device, and (d) the aging recovery effect of the transistor as a function of a usage parameter of the transistor device. The age-dependent analysis may include determining, for each of at least two of the multiple different values of the first operational parameter, a respective limit value derived from results of the multiple aging simulations performed for the respective value of the first operational parameter. The age-dependent analysis may also include determining the operational limit for the transistor device based at least on a result of the age-dependent analysis of the transistor device includes selecting a highest or lowest value of the at least two limit values as the operational limit for the transistor device.

In combination with any of the above examples, the instructions may be further executable by the processor to determine the operational limit for the transistor device based on a duration of an overvoltage stress applied to the transistor device.

In combination with any of the above examples, the non-aging simulation of the transistor device may include simulating an effect of the non-aging operation of the transistor device on a performance metric specified in the set of input parameters. The aging simulation of the transistor device may include simulating an effect of the aging operation of the transistor device on the performance metric.

### BRIEF DESCRIPTION OF THE DRAWINGS

The figures illustrate examples of systems and methods for determining an operational limit for a transistor device.

FIG. 1 illustrates an example system for generating and analyzing circuit designs using operational limits (e.g., SOA limits) for respective circuit components, according to examples of the present disclosure;

FIG. 2 illustrates an example operational limit generation system for generating operational limit (e.g., an SOA limit) for circuit component (e.g., a transistor), according to examples of the present disclosure;

FIG. 3 illustrates a flowchart of an example method 300 for determining an operational maximum voltage limit (Vmax) for an example circuit component, according to examples of the present disclosure;

FIG. 4 illustrates example graphs illustrating the regression models generated at block 324 described in FIG. 3, according to examples of the present disclosure;

FIG. 5 illustrates example graphs illustrating the bias temperature instability (BTI) recovery of a circuit component, according to examples of the present disclosure;

FIG. 6 illustrates example graphs illustrating the BTI recovery of a circuit component, according to examples of the present disclosure;

FIG. 7 illustrates a flowchart of an example method for generating an operational limit (e.g., maximum operating voltage) for a transistor device, according to examples of the present disclosure; and

FIG. 8 illustrates a flowchart of another example method for generating an operational limit (e.g., maximum operating voltage) for a transistor device, according to examples of the present disclosure.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect of the invention, systems and methods for determining an operational limit for a transistor device are provided. The systems and methods may allow for calculation of safe operating area (SOA) limits for hot carrier injection (HCI), bias temperature instability (BTI), or any combination thereof, without limitation, and account for the effects of recovery. BTI may be a reliability concern in Metal-Oxide-Semiconductor Field-Effect Transistors (MOSFETs) where the threshold voltage and other parameters of the transistor degrade over time when subjected to a gate bias at elevated temperatures. The degradation may be due to the generation of interface traps at the silicon/dielectric interface and charge trapping within the gate dielectric. However, circuits may recover from BTI when the stress conditions are removed or reduced. For example, when the gate voltage causing the stress is removed or reduced, the trapped charges can begin to detrap, and some of the generated interface traps can be annealed, allowing the threshold voltage to shift back towards its original value. Additionally, some circuits may not keep transistors under constant stress. For example, transistors switch between on and off states. During the “off” state or periods of inactivity for a particular transistor, it experiences a relaxation phase, allowing for partial recovery from the stress incurred during the “on” state. As another example, a designer may incorporate idle periods or lower-stress states for components, effectively duty-cycling the stress and allowing for intermittent recovery.

The calculations for determining an operational limit for a circuit component, accounting for recovery, may be integrated into an electronic design automation (EDA) tool and used within the design environment. As such, the Vmax limits may be generated and checked for compliance during the design process, potentially reducing the design cycle time because SOA limit checks may be performed at low-level schematic design during the design cycle. Thus, last minute fixes may be eliminated because aging simulations are not delayed and performed at the top level design cycle. The systems and methods may reduce the time and resources used to generate SOA limits and implementing SOA limit checks.

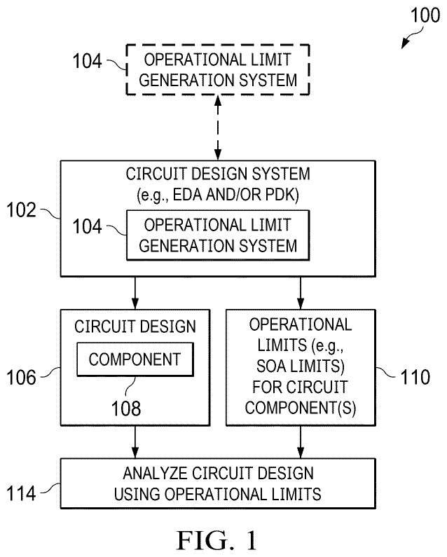

FIG. 1 illustrates an example system for generating and analyzing circuit designs using operational limits (e.g., SOA limits) for respective circuit components, according to examples of the present disclosure. Example system 100 may include circuit design system 102 and operational limit generation system 104. Circuit design system 102 may include any automated or semi-automated system or systems for generating and analyzing a circuit design 106 including various circuit components 108 (e.g., transistors), for example, an electronic design automation (EDA) tool (for example a Cadence, Synopsys, or Ansys EDA platform) to build and analyze circuit designs and/or a physical design kit (PDK) specific to a particular application or technology.

Operational limit generation system 104 may include circuitry to generate operational limits 110 (e.g., SOA limits) for respective circuit components 108 in circuit design 106. Operational limit generation system 104 may generate operational limits 110 for respective circuit components 108 based on respective input parameters (e.g., voltage specifications, operating temperature, minimum lifetime, maximum failure rate, transistor W/L, failure criteria). Circuit design system 102 may utilize operational limits 110 generated by operational limit generation system 104 to check circuit design 106 for compliance or design violations (e.g., at various stages during the construction of circuit design 106), as indicated at 114.

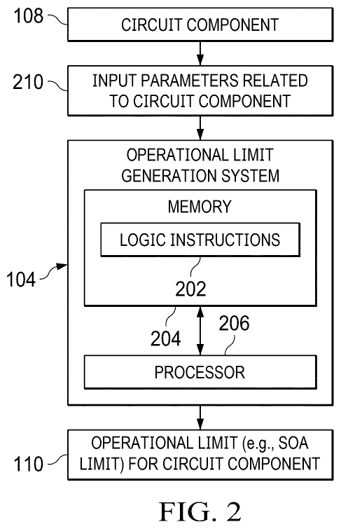

As discussed below with respect to FIG. 2, operational limit generation system 104 may comprise software or other computer-executable instructions stored in non-transitory computer-readable memory and executable by one or more processors. In some examples, operational limit generation system 104 may be integrated in circuit design system 102 (e.g., integrated in an EDA tool). In other examples, operational limit generation system 104 may be separate from circuit design system 102.

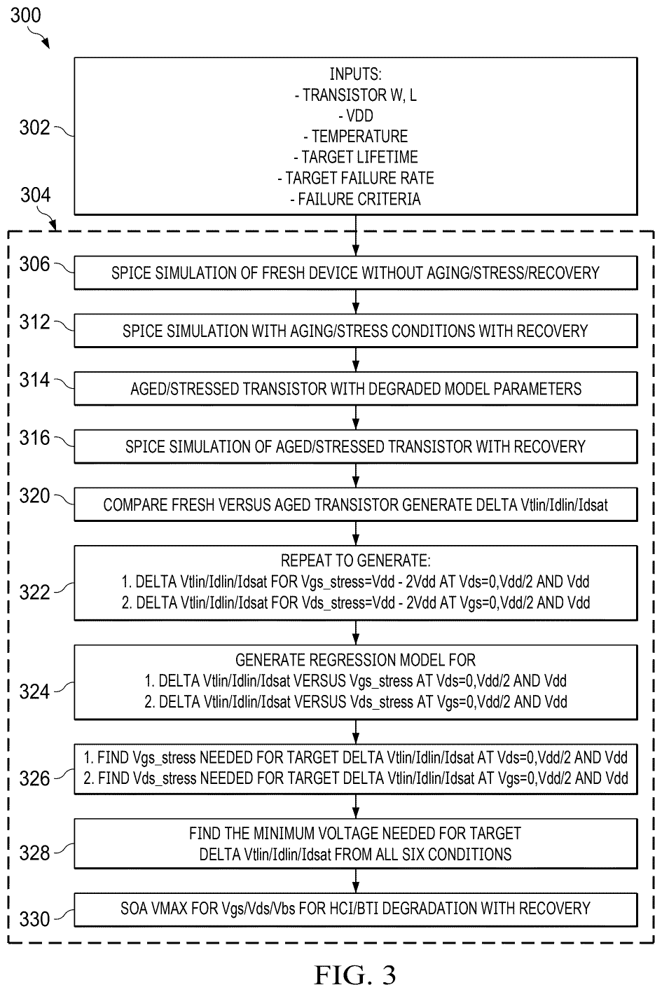

FIG. 2 illustrates an example operational limit generation system for generating operational limit (e.g., an SOA limit) for circuit component (e.g., a transistor), according to examples of the present disclosure. Operational limit 110 may be used by circuit design system 102 to check circuit design 106, as discussed above, according to examples of the present disclosure. As shown, operational limit generation system 104 may include computer-readable logic instructions 202 (e.g., embodied in software and/or firmware) stored in memory 204 and executable by a processor 206 to perform a respective process to generate operational limit 110, for example any of the example processes shown in FIG. 3 and discussed below.

Memory 204 may include one or more type of memory device to store logic instructions 202, for example, read-only memory (ROM), random access memory (RAM, SRAM, DRAM), electrically erasable programmable read-only memory (EEPROM), a PCMCIA card, flash memory, magnetic storage, opto-magnetic storage, hardware registers, and/or any suitable selection or array of volatile or non-volatile memory. Processor 206 may comprise any system, device, or apparatus operable to interpret or execute logic instructions 202, and may include, without limitation a microprocessor, microcontroller, digital signal processor (DSP), application specific integrated circuit (ASIC), or any other digital or analog circuitry to interpret or execute program instructions and/or process data.

As shown in FIG. 2, operational limit generation system 104 may receive input parameters 210 related to circuit component 108 (e.g., a transistor), and generate an operational limit 110 (e.g., a maximum gate voltage) for circuit component 108. FIG. 3 discussed below illustrates example processes implemented by operational limit generation system 104 (e.g., by execution of logic instructions 202 by processor 206) to generate an example operational limit 110 based on example input parameters 210.

FIG. 3 illustrates a flowchart of an example method 300 for determining an operational maximum voltage limit (Vmax) for an example circuit component, according to examples of the present disclosure. Method 300 may be at least partially implemented by operational limit generation system 104 shown in FIG. 2, for example by execution of respective logic instructions 202 (e.g., software) by processor 206, or any other system operable to implement method 300. The discussion of method 300 below is directed to the example transistor simulation; however, the transistor is one example, such that method 300 may be similarly applied to other circuit components. Although examples have been described above, other variations and examples may be made from this disclosure without departing from the spirit and scope of these disclosed examples.

In some examples, method 300 results in a value of Vmax that is adopted as the operational limit (Vmax) for the circuit component. In other examples, method 300 outputs a value of Vmax that is compared with at least one other value of Vmax output by other process(es) to determine the operational limit (Vmax) for the circuit component.

At block 302, the operational limit generation system may receive a set of input parameters related to the example circuit component (e.g., a transistor). For example, the set of input parameters may specify:
(a) dimensions of the circuit component (e.g., width=10 microns, length=100 nm),
(b) maximum operating voltage Vdd (e.g., 0.9V),
(c) maximum operating temperature of the circuit component (e.g., 125° C., maximum junction temperature of transistor),
(d) target lifetime (e.g., 10 years),
(e) target failure rate (e.g., 1000 ppm), and
(f) failure criteria (e.g., 10% change (degradation) in saturation current (ΔIdsat)).

In other examples, the failure criteria may specify a maximum change in linear drain current (Idlin) (e.g., ΔIdlin=10%) or linear threshold voltage (Vtlin) (e.g., ΔVtlin=10%), or alternatively the input parameters may specify multiple alternative failure criteria, for example, ΔIdsat=10% ΔIdlin=10%, or ΔVtlin=10%.

At block 304, the operational limit generation system may perform an operational limit generation process to generate an operational limit for the circuit component with respect to respective failure modes, in particular failures from hot carrier injection (HCI) degradation or bias temperature instability (BTI) including aging recovery of the circuit component. In some examples, the operational limits may be generated to account for separate and combined HCI and BTI including recovery of the circuit component. Block 304 may include block 306 through block 330.

At block 306, the operational limit generation system may perform a non-aging simulation of the circuit component by simulating a non-aging operation of the circuit component, for example, based on one or more of the input parameters, for example using a SPICE circuit simulator program. Simulating a non-aging operation of the circuit component may include (a) generating non-aged model of the circuit component based on respective input parameters received at block 302 (e.g., dimensions, materials, operating specifications of the circuit component), and (b) operating the non-aged model according to respective input parameters received at block 302 (e.g., Vdd, use temperature), and without considering time-based degradation (i.e., aging) or effects of recovery of the circuit component, to determine a resulting value of a target performance metric specified by the input parameters (e.g., in this example, Idsat).

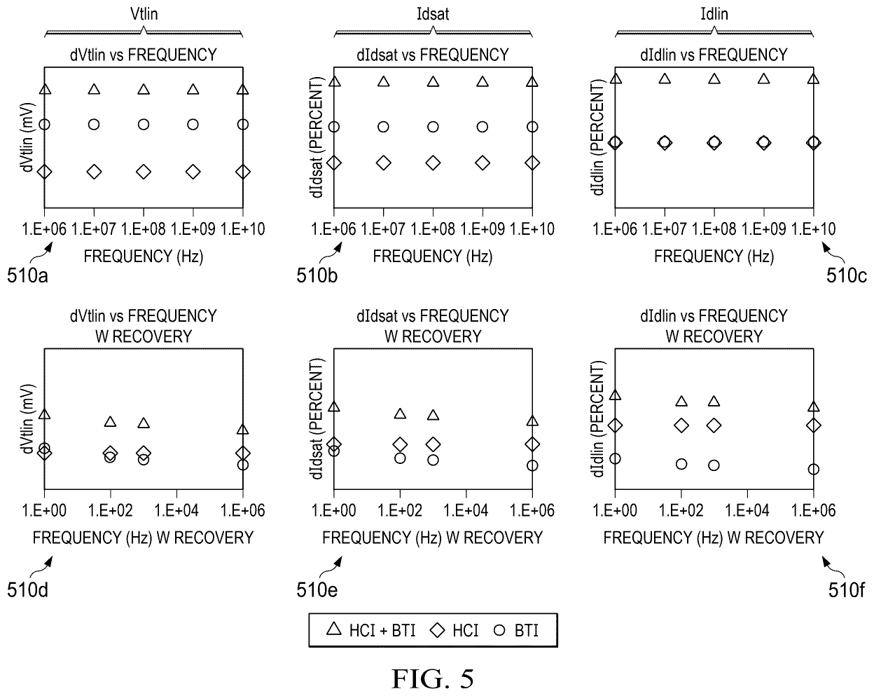

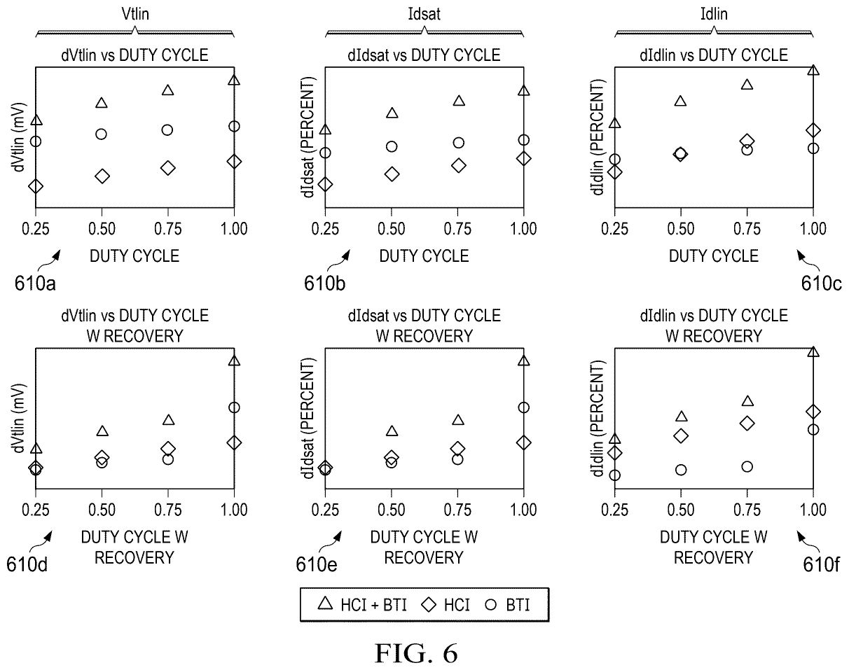

At block 312, the operational limit generation system may perform aging simulations of the circuit component. The aging simulations may be performed using selected parameter values and may account for aging recovery of the circuit component. For example, the operational limit generation system may select values of an operational parameter (e.g., Vds and Vgs) to analyze, for example by selecting Vds to analyze through a range of Vds values from Vdd to 2*Vdd, and using a selected Vgs value (Vgs=Vdd). First, the operational limit generation system may simulate (e.g., using a SPICE simulator) an operation of the non-aged model generated at block 306 for a first value of the operational parameter, Vds in the specified range of Vdd to 2*Vdd, and using Vgs=0. For example, the operational limit generation system may perform a first simulation using Vds=Vdd and Vgs=0, applied for the target lifetime of 10 years. The accounting for aging recovery of the circuit component may be a function of duty cycle, frequency, or any combination thereof. FIGS. 5 and 6 illustrate how the aging recovery of the circuit component changes based on frequency and duty cycle, respectively.

The simulation at block 312 may alter certain characteristics of the circuit component, e.g., gate oxide charge, electron/hole mobility. At block 314, the simulator program (e.g., a SPICE simulator) may generate an aged model of the circuit component based on such altered characteristics of the circuit component.

At block 316, the operational limit generation system may then operate the aged model using Vds=Vgs=Vdd (0.9V in this example) to determine a respective Idsat value. The respective Idsat value may account for the aging recovery of the circuit component.

The operational limit generation system may repeat the process of blocks 312-316 for each other value of Vds, for example Vds=Vdd, Vds=1.2*Vdd, Vds=1.4*Vdd, Vds=1.6*Vdd, Vds=1.8*Vdd, and Vds=2*Vdd, to determine a respective Idsat value for each value of Vds, accounting for aging recovery of the circuit component.

At block 320, the operational limit generation system may compare the results of the aging simulations from block 316 with the results (e.g., the Idsat value) of the non-aging simulation from block 306.

At block 322, the operational limit generation system may repeat the process at blocks 312-320 to analyze the operational parameters (e.g., Vds) values using other values of Vgs (e.g., Vgs=0 and Vgs=Vdd/2), and the process for analyzing Vds discussed above (i.e., at blocks 312-322) may be repeated to analyze Vgs (i.e., by analyzing Vgs through a range of values from Vdd to 2*Vdd, and using selected Vds value (0, Vdd/2, and Vdd), to generate respective ΔIdsat results for each combination of parameter values.

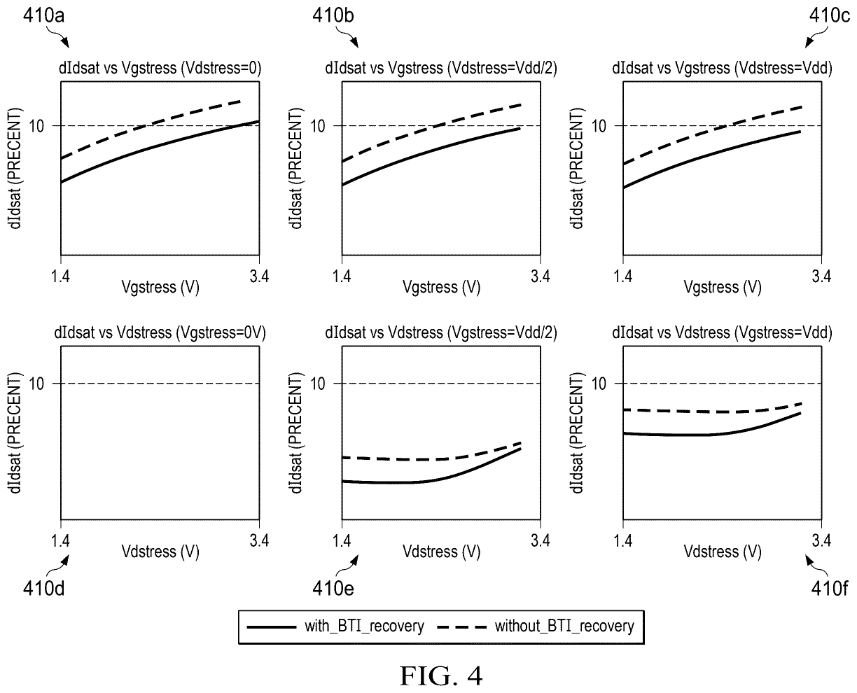

At block 324, the operational limit generation system may generate a regression model for each respective failure criteria (e.g., ΔVtlin, ΔIdlin, ΔIdsat) at the operational parameters (e.g., Vds, Vgs). FIG. 4 illustrates example graphs illustrating the regression models generated at block 324 described in FIG. 3, according to examples of the present disclosure.

At block 326, the operational limit generation system may determine a respective limit value (Vmax) for each regression models generated at block 324. For example, as shown in FIG. 4, for graphs 410a-410c, a respective Vmax limit value, including aging recovery, may be determined as the value of Vgs (if any) for which the regression line exceeds the target ΔIdsat (e.g., 10%) (specified in the input parameters received at block 302). In this example, a limit value of Vmax=3.2V is determined from graph 410a. The target ΔIdsat in graph 410b has a limit value of Vmax=3.35V and the target ΔIdsat in graph 410c has a limit value of Vmax>3.4V. The lowest Vmax is selected, resulting in a limit value of Vmax=3.2V as shown in graph 410a. As shown in graphs 410a-410c, if recovery effects are not considered, a lower Vmax would be generated by the model (e.g., 2.25V as shown in graph 410a). Therefore, it is essential to incorporate the impact of BTI recovery to determine the Vmax limit for a more realistic aging prediction.

Similarly, for graphs 410d-410e, a respective Vmax limit value may be determined as the value of Vds (if any) for which the regression line exceeds the target ΔIdsat (e.g., 10%). In this example, as shown in FIG. 4, the target ΔIdsat is not exceeded in graphs 410d-410e at the voltages plotted when aging recovery effects are considered.

In some examples, an overall voltage limit value for the circuit component may be selected. In other examples, different voltage limit values may be selected for different terminals of the circuit component. For example, the drain may have a first voltage limit, the gate may have a second voltage limit, the body may have a third voltage limit, and the source may have a fourth voltage limit.

At block 328, the operational limit generation system may determine a minimum limit value from the various Vmax limit values determined at block 326, in this example Vmax=3.2V shown in graph 410a. In this example, this minimum limit value (Vmax=3.2V) may be specified as the operational maximum voltage limit for the transistor with respect to potential hot carrier injection (HCI) degradation, bias temperature instability (BTI), or a combination thereof, accounting for the effects of recovery, according to the input parameters received at block 302. In an example in which multiple failure criteria are specified by the input parameters, for example, ΔIdsat=10% ΔIdlin=10%, or ΔVtlin=10%, the process described above may be repeated for each respective failure criteria (e.g., ΔIdsat, ΔIdlin, and ΔVtlin) to determine respective limit values, which may be compared to determine an operational maximum voltage limit (e.g., the lowest limit value). The maximum voltage limits may then be used to check a circuit design within a design environment to ensure that the design complies with the maximum allowable voltage limit such that the circuit may perform within the design specifications over the circuits intended lifespan.

Method 300 may be used to generate separate voltage limits for different terminals of the circuit component (e.g., drain, gate, body, source). Method 300 may also account for BTI recovery based on duty cycle and frequency. SOA limits may be generated based on specific use cases of geometry, temperature, lifetime, failure rate, failure criteria, or any combination thereof, in terms of delta Vtlin, Idsat, Idlin or any combination thereof.

Although FIG. 3 discloses a particular number of operations related to method 300, method 300 may be executed with greater or fewer operations than those depicted in FIG. 3. In addition, although FIG. 3 discloses a certain order of operations to be taken with respect to method 300, the operations comprising method 300 may be completed in any suitable order.

FIG. 5 illustrates example graphs illustrating the BTI recovery of a circuit component, according to examples of the present disclosure. In the example shown in FIG. 5, the effects of HCI and BTI on a circuit component are illustrated with and without consideration of aging recovery. Graphs 510a-510c illustrate Vtlin, Idsat, and Idlin, respectively, as a function of frequency, without accounting for the recovery of the circuit component. Graphs 510d-510f illustrate Vtlin, Idsat, and Idlin, respectively, as a function of frequency, with accounting for the aging recovery of the circuit component. Comparing graphs 510a-510c with graphs 510d-510e illustrates how the aging degradation of the circuit component may be overestimated when aging recovery effects are not considered.

FIG. 6 illustrates example graphs illustrating the BTI recovery of a circuit component, according to examples of the present disclosure. In the example shown in FIG. 6, the effects of HCI and BTI on a circuit component are illustrated with and without consideration of aging recovery. Graphs 610a-610c illustrate Vtlin, Idsat, and Idlin, respectively, as a function of duty cycle, without accounting for the aging recovery of the circuit component. Graphs 610d-610f illustrate Vtlin, Idsat, and Idlin, respectively, as a function of duty cycle, with accounting for the aging recovery of the circuit component. Comparing graphs 610a-610c with graphs 610d-610e illustrates how the degradation of the circuit component may be overestimated when aging recovery effects are not considered. As the duty cycle increases, the aging recovery effects are reduced because the circuit component has less time to recover.

The circuit component may be able to tolerate lower over-voltage stresses for longer periods of time and higher over-voltage stresses for shorter periods of time. Therefore, the operational limit generation system may calculate a voltage limit by taking into account the duration of the over-voltage stress. In some examples, the operational limit generation system may allow a higher voltage limit when the high voltage may only be experienced by the circuit component for a short period of time.

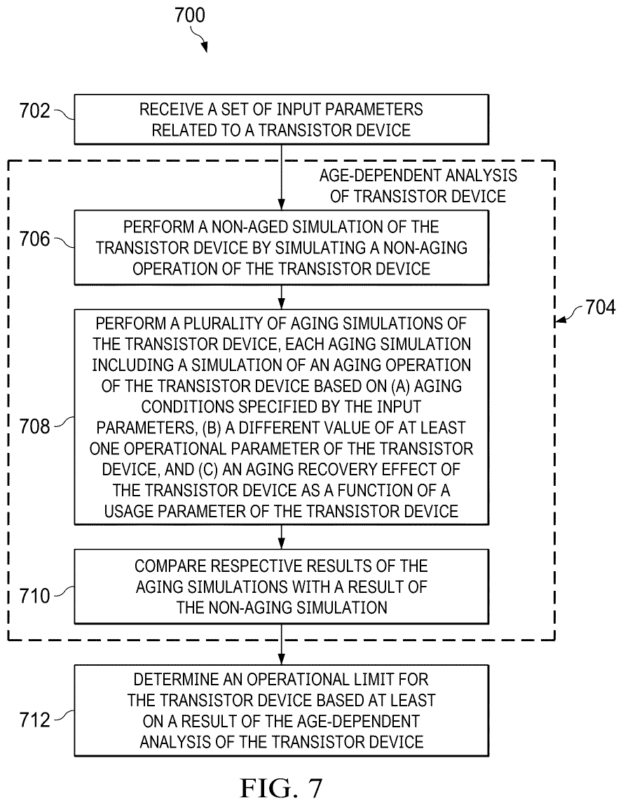

FIG. 7 illustrates a flowchart of an example method 700 for generating an operational limit (e.g., maximum operating voltage) for a transistor device, according to examples of the present disclosure. The example method 700 may be implemented by an operational limit generation system, such as operational limit generation system 104 shown in FIG. 2, for example by execution of respective logic instructions 202 (e.g., software) by processor 206.

At block 702, the operational limit generation system may receive a set of input parameters related to a transistor device, e.g., a transistor device to be included in a circuit design for a particular application. The input parameters may include, for example, characteristics of the transistor device itself (e.g., size, operating specifications), parameters related to an expected operation of the transistor device (e.g., temperature), and/or “aging conditions” related to the transistor device (e.g., a target lifetime, a failure rate, and/or particular failure mode(s) to be analyzed).

At block 704, the operational limit generation system may perform an age-dependent analysis of the transistor device based on the set of input parameters. The age-dependent analysis may include blocks 706-710, which may be performed in any order and may be performed at least partially simultaneously.

At block 706, the operational limit generation system may perform a non-aging simulation of the transistor device by simulating a non-aging operation of the transistor device, for example, based on one or more of the input parameters, for example using a SPICE circuit simulator program. Simulating a non-aging operation of the transistor device may include (a) generating a model of a freshly manufactured instance of the transistor device, referred to as a “non-aged model” of the transistor device, based on respective input parameters (e.g., dimensions, materials, operating specifications of the transistor device), and (b) operating the non-aged model according to respective input parameters (e.g., Vdd, use temperature), and without considering time-based degradation (i.e., aging) of the transistor device, to determine a resulting value of a target performance metric (e.g., a saturation current Idsat) specified by the input parameters.

At block 708, the operational limit generation system may perform a plurality of aging simulations of the transistor device. Each aging simulation may comprise an extended simulation of an aging operation of the transistor device based on (a) aging conditions specified by the input parameters, (b) selected value(s) of at least one operational parameter of the transistor device, and (c) an aging recovery effect of the transistor device as a function of a usage parameter of the transistor device, to determine a respective value of the target performance metric (e.g., a saturation current Idsat) resulting from such simulated operation. In one example, the operational limit generation system may use a SPICE circuit simulator program or other suitable program(s) to (a) apply selected operational parameter value(s) (e.g., Vds, Vgs, temperature) to the transistor device for the target lifetime specified by the input parameters, which may alter certain characteristics of the transistor device (e.g., gate oxide charge, electron/hole mobility), (b) generate an “aged model” of the transistor device based on such altered characteristics of the transistor device, and (c) operate the aged model to determine a value of the target performance metric (e.g., Idsat).

Different operational parameter value(s) (e.g., Vds, Vgs, temperature) may be used for each aging simulation of the transistor device, to thereby evaluate the effect of varying the operational parameter(s) on the target performance metric. For example, for a transistor device comprising a transistor, each aging simulation may use a different combination of Vgs and Vds values, to evaluate the effect of varying Vgs and/or Vds on the target performance metric.

At block 710, the operational limit generation system may compare respective results of each aging simulation from block 708 with the results of the non-aging simulation from block 706, wherein the non-aging simulation from block 706 represents a baseline or reference. For example, as discussed below, the operational limit generation system may determine a change in performance (e.g., Idsat value) between each aging simulation and the reference non-aging simulation.

At block 712, the operational limit generation system may determine an operational limit (e.g., maximum gate voltage) for the transistor device based at least on a result of the age-dependent analysis of the transistor device. For example, the operational limit generation system may determine from the various comparisons from block 710 a lowest voltage that may violate a performance requirement specified by the input parameters (e.g., maximum drop in Idsat), and set such lowest voltage as the maximum gate voltage (i.e., operational limit) for the transistor device.

Although FIG. 7 discloses a particular number of operations related to method 700, method 700 may be executed with greater or fewer operations than those depicted in FIG. 7. In addition, although FIG. 7 discloses a certain order of operations to be taken with respect to method 700, the operations comprising method 700 may be completed in any suitable order.

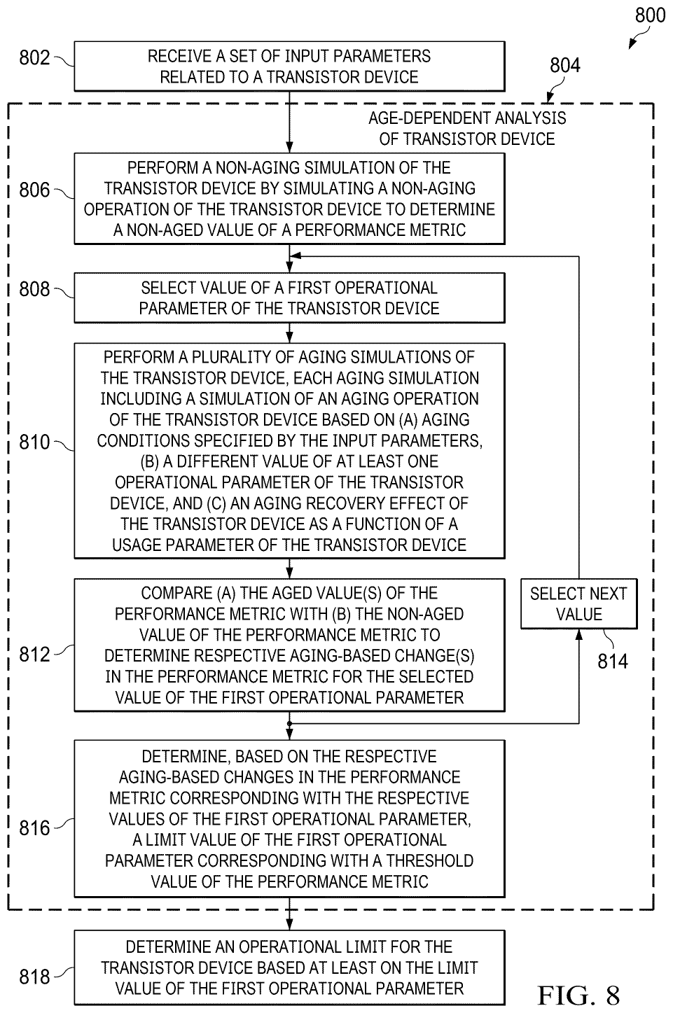

FIG. 8 illustrates a flowchart of another example method 800 for generating an operational limit (e.g., maximum operating voltage) for a transistor device, according to examples of the present disclosure. The example method 800 may be implemented by an operational limit generation system, such as operational limit generation system 104 shown in FIG. 2, for example by execution of respective logic instructions 202 (e.g., software) by processor 206.

At block 802 (similar to block 702 discussed with respect to FIG. 7), the operational limit generation system may receive a set of input parameters related to a transistor device, e.g., a transistor device to be included in a circuit design for a particular application.

At block 804, the operational limit generation system may perform an age-dependent analysis of the transistor device based on the set of input parameters. The age-dependent analysis may include blocks 806-816, which may be performed in any order and may be performed at least partially simultaneously.

At block 806, the operational limit generation system may perform a non-aging simulation of the transistor device by simulating a non-aging operation of the transistor device, for example, based on one or more of the input parameters, for example using a SPICE circuit simulator program. As discussed above, simulating a non-aging operation of the transistor device may include (a) generating non-aged model of the transistor device based on respective input parameters (e.g., dimensions, materials, operating specifications, of the transistor device), and (b) operating the non-aged model according to respective input parameters (e.g., Vdd, use temperature), and without considering time-based degradation (i.e., aging) of the transistor device, to determine a resulting value of a target performance metric (e.g., a saturation current Idsat) specified by the input parameters.

At blocks 808-812, the operational limit generation system may analyze a first operational parameter of the transistor device (e.g., Vds) to generate data for determining a limit value of the first operational parameter at block 816.

At block 808, the operational limit generation system may select a first value of the first operational parameter (e.g., Vds=Vdd, wherein Vdd is specified by the input parameters).

At block 810, the operational limit generation system may perform one or more aging simulations of the transistor device using the first value of the first operational parameter (e.g., Vds=Vdd). Each aging simulation may comprise an extended simulation of an aging operation of the transistor device based on (a) aging conditions specified by the input parameters, (b) the first value of the first operational parameter (e.g., Vds=Vdd), and (c) an aging recovery effect of the transistor device as a function of a usage parameter of the transistor device, to determine a value of the target performance metric (e.g., a saturation current Idsat) resulting from such simulated operation.

In some examples, multiple aging simulations are performed using the first value of the first operational parameter (e.g., Vds=Vdd), for example using a different value of a second operational parameter (e.g., Vgs) for each respective aging simulation. Thus, each aging simulation from block 810 may use (a) aging conditions specified by the input parameters, (b) the first value of the first operational parameter (e.g., Vds=Vdd), and (c) a different value of the second operational parameter (e.g., Vgs=0, Vgs=Vdd/2, and Vgs=Vdd for three distinct aging simulations), to determine respective value of the target performance metric (e.g., Idsat) resulting from such simulated operation. Vds and Vgs values applied during an aging simulation may be referred to herein as Vds_stress and Vgs_stress, respectively.

In some examples, the operational limit generation system may use a SPICE circuit simulator program or other suitable program(s) for each aging simulation, wherein the first value of the first operational parameter (e.g., Vds=Vdd) and the respective value of the second operational parameter (e.g., Vgs=0, Vdd/2, or Vdd) for the target lifetime specified by the input parameters, may alter certain characteristics of the transistor device (e.g., gate oxide charge, electron/hole mobility). The simulator program (e.g., a SPICE simulator) may then generate an aged model of the transistor device based on the altered characteristics of the transistor device, and operate the aged model to determine a respective value of the target performance metric (e.g., Idsat).

At block 812, the operational limit generation system may compare respective results of each aging simulation from block 810 with the results of the non-aging simulation from block 806, wherein the non-aging simulation from block 806 represents a baseline or reference. For example, the operational limit generation system may determine a change in performance (e.g., ΔIdsat) between each aging simulation and the reference non-aging simulation.

The operational limit generation system may then select a next value (e.g., a second value) for the first operational parameter (e.g., Vds=1.2*Vdd) and repeat the process of blocks 810 and 812. The operational limit generation system may continue this process for all values of the first operational parameter to be tested, for example for a range of values of Vds from Vdd to 2*Vdd.

At block 816, the operational limit generation system may determine a limit value for the first operational parameter based on the results of the analysis at blocks 808-814, for example based on the respective change in the performance metric (e.g., ΔIdsat) resulting from each iteration, i.e., the ΔIdsat resulting from each selected combination of Vds and Vgs values.

At block 816, the operational limit generation system may determine an operational limit of the transistor device (e.g., maximum gate voltage of a transistor) based at least on the limit value determined at block 816. For example, as discussed with reference to FIG. 3, the operational limit generation system may repeat the age-dependent analysis at block 804 for additional operational parameter(s) (e.g., the second operational parameter (Vgs)) and determine respective limit value(s) for such operational parameter(s), which may be compared with the limit value for the first operational parameter (Vds) to determine the operational limit of the transistor device, e.g., by selecting the lowest determined limit value.

Although FIG. 8 discloses a particular number of operations related to method 800, method 800 may be executed with greater or fewer operations than those depicted in FIG. 8. In addition, although FIG. 8 discloses a certain order of operations to be taken with respect to method 800, the operations comprising method 800 may be completed in any suitable order.

Although examples have been described above, other variations and examples may be made from this disclosure without departing from the spirit and scope of these disclosed examples.

1. A non-transitory computer-readable medium comprising instructions executable by a processor to:
receive a set of input parameters related to a transistor device;
perform an age-dependent analysis of the transistor device based on the set of input parameters, including:
performing a non-aging simulation of the transistor device by simulating a non-aging operation of the transistor device;
performing a series of aging simulations of the transistor device, each aging simulation comprising a simulation of an aging operation of the transistor device based on (a) aging conditions specified by the input parameters, (b) a different value of at least one operational parameter of the transistor device, wherein at least one operational parameter of the transistor device comprises at least one of a gate-source voltage (Vgs), a drain-source voltage (Vds), or a body-source voltage (Vbs), and (c) an aging recovery effect of the transistor device as a function of a usage parameter of the transistor device;
comparing respective results of the series of aging simulations with a result of the non-aging simulation; and
determine an operational limit for the transistor device based at least on a result of the age-dependent analysis of the transistor device, wherein the operational limit comprises a maximum operating value of the gate-source voltage (Vgs), the drain-source voltage (Vds), or the body-source voltage (Vbs).

2. The non-transitory computer-readable medium of claim 1, wherein the instructions are further executable by the processor to apply the operational limit to a circuit design to detect design violations.

3. The non-transitory computer-readable medium of claim 1, wherein the operational limit includes a safe operating area (SOA) limit for the transistor device.

4. The non-transitory computer-readable medium of claim 1, wherein the non-aging simulation and the plurality of aging simulations of the transistor device are performed by a SPICE simulator.

5. The non-transitory computer-readable medium of claim 1, wherein the aging simulation in the plurality of aging simulations of the transistor device includes a simulation of the aging operation of the transistor device based on (a) the aging condition specified by the input parameters, (b) a different parameter value combination for at least two operational parameters of the transistor device, and (c) the aging recovery effect of the transistor device as a function of a usage parameter of the transistor device.

6. The non-transitory computer-readable medium of claim 1, wherein:
performing the plurality of aging simulations of the transistor device includes performing multiple aging simulations of the transistor device for each of multiple different values of a first operational parameter of the transistor device, wherein the multiple aging simulations for a respective value of the first operational parameter includes respective aging simulations based on (a) the aging condition specified by the input parameters, (b) the respective value of the first operational parameter, (c) multiple different values of a second operational parameter of the transistor device, and (d) the aging recovery effect of the transistor device as a function of a usage parameter of the transistor device;
the age-dependent analysis includes:
determining, for each of at least two of the multiple different values of the first operational parameter, a respective limit value derived from results of the multiple aging simulations performed for the respective value of the first operational parameter; and
determining the operational limit for the transistor device based at least on a result of the age-dependent analysis of the transistor device includes selecting a highest or lowest value of the at least two limit values as the operational limit for the transistor device.

7. The non-transitory computer-readable medium of claim 1, wherein the instructions are further executable by the processor to determine the operational limit for the transistor device based on a duration of an overvoltage stress applied to the transistor device.

8. The non-transitory computer-readable medium of claim 1, wherein:
the non-aging simulation of the transistor device includes simulating an effect of the non-aging operation of the transistor device on a performance metric specified in the set of input parameters; and
the aging simulation of the transistor device includes simulating an effect of the aging operation of the transistor device on the performance metric.

9. The non-transitory computer-readable medium of claim 8, wherein the performance metric is a saturation drain current (Idsat), a linear drain current (Idlin), or a linear threshold voltage (Vtlin).

10. The non-transitory computer-readable medium of claim 1, wherein:
performing the non-aging simulation of the transistor device includes simulating a non-aging operation of a non-aged model of the transistor device derived from the set of input parameters; and
performing a respective aging simulation of the transistor device in the plurality of aging simulations includes:
simulating an aging operation of the non-aged model of the transistor device;
generating an aged model of the transistor device based on results of the aging operation of the non-aged model of the transistor device; and
simulating an operation of the aged model of the transistor device.

11. A method, comprising:
receiving a set of input parameters related to a transistor device;
performing an age-dependent analysis of the transistor device based on the set of input parameters, including:
performing a non-aging simulation of the transistor device by simulating a non-aging operation of the transistor device;
performing a plurality of aging simulations of the transistor device, an aging simulation of the plurality of aging simulations including a simulation of an aging operation of the transistor device based on (a) aging conditions specified by the input parameters, (b) a different value of at least one operational parameter of the transistor device, wherein at least one operational parameter of the transistor device comprises at least one of a gate-source voltage (Vgs), a drain-source voltage (Vds), or a body-source voltage (Vbs), and (c) an aging recovery effect of the transistor as a function of a usage parameter of the transistor device;
comparing respective results of the plurality of aging simulations with a result of the non-aging simulation; and
determining an operational limit for the transistor device based at least on a result of the age-dependent analysis of the transistor device, wherein the operational limit comprises a maximum operating value of the gate-source voltage (Vgs), the drain-source voltage (Vds), or the body-source voltage (Vbs).

12. The method of claim 11, wherein the aging simulation in the plurality of aging simulations of the transistor device includes a simulation of the aging operation of the transistor device based on (a) the aging condition specified by the input parameters, (b) a different parameter value combination for at least two operational parameters of the transistor device, and (c) the aging recovery effect of the transistor device as a function of a usage parameter of the transistor device.

13. The method of claim 11, wherein:
performing the plurality of aging simulations of the transistor device includes performing multiple aging simulations of the transistor device for each of multiple different values of a first operational parameter of the transistor device, wherein the multiple aging simulations for a respective value of the first operational parameter includes respective aging simulations based on (a) the aging conditions specified by the input parameters, (b) the respective value of the first operational parameter, (c) multiple different values of a second operational parameter of the transistor device, and (d) the aging recovery effect of the transistor as a function of a usage parameter of the transistor device;
the age-dependent analysis includes:
determining, for each of at least two of the multiple different values of the first operational parameter, a respective limit value derived from results of the multiple aging simulations performed for the respective value of the first operational parameter; and
determining the operational limit for the transistor device based at least on a result of the age-dependent analysis of the transistor device includes selecting a highest or lowest value of the at least two limit values as the operational limit for the transistor device.

14. The method of claim 11, comprising determining the operational limit for the transistor device based on a duration of an overvoltage stress applied to the transistor device.

15. The method of claim 11, wherein:
the non-aging simulation of the transistor device includes simulating an effect of the non-aging operation of the transistor device on a performance metric specified in the set of input parameters; and
the aging simulation of the transistor device includes simulating an effect of the aging operation of the transistor device on the performance metric.

16. A system, comprising:
an electronic design automation (EDA) tool for development of circuit design including a transistor device;
an operational limit generation system integrated in the EDA tool, the operational limit generation system including instructions stored in non-transitory computer-readable medium and executable by a processor to:
receive a set of input parameters related to a transistor device;
perform an age-dependent analysis of the transistor device based on the set of input parameters, including:
performing a non-aging simulation of the transistor device by simulating a non-aging operation of the transistor device;
performing a plurality of aging simulations of the transistor device, an aging simulation of the plurality of aging simulations including a simulation of an aging operation of the transistor device based on (a) aging conditions specified by the input parameters, (b) a different value of at least one operational parameter of the transistor device, wherein at least one operational parameter of the transistor device comprises at least one of a gate-source voltage (Vgs), a drain-source voltage (Vds), or a body-source voltage (Vbs), and (c) an aging recovery effect of the transistor as a function of a usage parameter of the transistor device;
comparing respective results of the plurality of aging simulations with a result of the non-aging simulation; and
determine an operational limit for the transistor device based at least on a result of the age-dependent analysis of the transistor device, wherein the operational limit comprises a maximum operating value of the gate-source voltage (Vgs), the drain-source voltage (Vds), or the body-source voltage (Vbs).

17. The system of claim 16, wherein the aging simulation in the plurality of aging simulations of the transistor device includes a simulation of the aging operation of the transistor device based on (a) the aging condition specified by the input parameters, (b) a different parameter value combination for at least two operational parameters of the transistor device, and (c) the aging recovery effect of the transistor device as a function of a usage parameter of the transistor device.

18. The system of claim 16, wherein:
performing the plurality of aging simulations of the transistor device includes performing multiple aging simulations of the transistor device for each of multiple different values of a first operational parameter of the transistor device, wherein the multiple aging simulations for a respective value of the first operational parameter includes respective aging simulations based on (a) the aging conditions specified by the input parameters, (b) the respective value of the first operational parameter, (c) multiple different values of a second operational parameter of the transistor device, and (d) the aging recovery effect of the transistor as a function of a usage parameter of the transistor device;
the age-dependent analysis includes:
determining, for each of at least two of the multiple different values of the first operational parameter, a respective limit value derived from results of the multiple aging simulations performed for the respective value of the first operational parameter; and
determining the operational limit for the transistor device based at least on a result of the age-dependent analysis of the transistor device includes selecting a highest or lowest value of the at least two limit values as the operational limit for the transistor device.

19. The system of claim 16, wherein the instructions are further executable by the processor to determine the operational limit for the transistor device based on a duration of an overvoltage stress applied to the transistor device.

20. The system of claim 16, wherein:
the non-aging simulation of the transistor device includes simulating an effect of the non-aging operation of the transistor device on a performance metric specified in the set of input parameters; and
the aging simulation of the transistor device includes simulating an effect of the aging operation of the transistor device on the performance metric.
